(19) United States
(12) Patent Application Publication
(10) Pub. No.: US 2007/0248898 A1
(43) Pub. Date: Oct. 25, 2007

(54) TARGETS FOR ALIGNMENT OF SEMICONDUCTOR MASKS

(75) Inventor: Herve Rivoal, St. Maximin (FR)

Correspondence Address: SCHNECK & SCHNECK, P.O. BOX 2-E, SAN JOSE, CA, 95109-0005, US

(73) Assignee: Atmel Corporation, San Jose, CA (US)

(21) Appl. No.: 11/379,512

(22) Filed: Apr. 20, 2006

(51) Int. Cl. H01L 23/58; G03B 27/42; H01L 23/544; G03F 1/00; G03F 9/00; G03C 5/00; H01L 29/10

(52) U.S. Cl. 430/22; 430/5; 430/30; 257/48; 257/797; 438/975; 355/53

(57) ABSTRACT

Alignment of mask layers in semiconductor manufacturing is carried out by using alignment lines having at least one row of diffractively reflecting or scattering features on the lines. The features are made using a phase shift mask which, in combination with selected photoresist, suppresses second and higher order lobes, thereby allowing the features to be more closely spaced than by lithography. The features appear as light reflecting or scattering dots or spots in rows on ridges of standard or non-standard alignment lines. Laser light of only one color is used for mask alignment.

### TECHNICAL FIELD

The invention relates to semiconductor manufacturing tools and, in particular, targets for mask alignment in step and repeat scan systems.

### BACKGROUND ART

In wafer fabrication, a reticle or mask is a partially light transmissive substrate having a pattern image for a step and repeat scanning exposure of a surface of a wafer by a beam directed through the reticle or mask. A reticle is usually smaller than a mask but may reside in the same position in a stepper and so the term mask or photomask as used herein is applicable to reticles. Several levels of masks are typically needed to pattern a wafer with layers of materials needed to form complete integrated circuits. Each mask level creates an image in photoresist that is applied across at least a portion of a wafer. The photoresist is etched to form topographic, i.e. three dimensional, patterns that are used to create features on the wafer using deposition or growth or implantation of various insulative and conductive materials. Once the features are created, the photoresist is removed and layered semiconductor devices are thus formed. Step and repeat scanners of the type described, commonly known as “steppers”, are commercially available.

Alignment of masks between layers: is carried out with alignment patterns that form a part of each mask level. FIG. 1 shows a stepper of the prior art, in this example an ASML system, where “ASML” is a registered trademark of ASM Lithography B. V., La Veldhoven, The Netherlands. Such a system employs an excimer laser 11 to generate a beam 13 that is directed by mirrors 15a-15e through a first series of lenses 16 for shaping to impinge upon a mask 17 and then through a second series of lenses 19 for further shaping prior to impingement on wafer 21. While sometimes a mask is placed in contact with a wafer, the present application involves semiconductor manufacturing where a mask is located at a location for projection onto the wafer for at least some of the manufacturing steps. The mask image carries alignment marks that are compared with features on a lower level for registration. A next higher level must be aligned with the immediate lower level. Principal alignment marks are formed on the wafer itself. Alignment marks are visible on each successive level.

The alignment marks are projected from one or more targets that are themselves masks. There are alignment marks for each mask level. A prior art alignment target is shown in FIG. 2. For example, a feature of mask level 2 is to be found within a feature of mask level 1. There could be a rule that edges of the level 1 featured never touch the edges of the level 2 feature. Tolerances are established between edges of the features and these become design rules for manufacturing the wafer. Target marks are seen from the top down. Images of the level 2 target within the level 1 target are reflected back to a microscope where the image is digitized for computer analysis for an indication of whether alignment exists.

Some wafer alignment can be carried out along the optical axis of the stepper. However, other alignment is carried out off-axis using separate lasers having a very small beam spot, sometimes of diverse wavelengths, such as red and green lasers for computer analysis of overlays using feedback to correct alignment. There are various targets for various alignment strategies and needs. All employ closely spaced lines or geometric patterns. There are commercial targets to achieve these needs and strategies where an overlay target has lines spaced and having a thickness for determining whether they are in registration with a lower level line pattern in accordance with design rules.

One of the problems that occurs today is that in today's sub-micron line width environment, target lines are so fine and closely spaced that resolution becomes difficult. To achieve good resolution, lines must be spaced further apart than desired. It is typical that diffraction patterns are used to identify line spacings. Standard targets known as SPM-AH74 and SPM-AH53 yield high order diffraction patterns. Alignment strategies are devised to take into account multiple diffraction orders and to select an order that has good signal strength, i.e. resolution. For example, perhaps the fifth order or the seventh order has good strength and in such a situation, other orders must be suppressed or otherwise not considered. Also, since two wavelengths are used, red and green, 633 nm and 532 nm respectively, the signal strength at each wavelength, as well as each diffraction order, should be considered. With these many variables, there is sometimes poor alignment repeatability, even though good combinations of variables can be found for one alignment. What is desired is a simplified alignment target that achieves at least as high resolution as achieved in the prior art and that has good alignment repeatability.

### SUMMARY OF THE INVENTION

To form an alignment pattern, actinic radiation is directed through a mask with alignment marks for etching of a line pattern at the contact level. In accordance with the invention, another mask or reticle induces deformations in the nature of pits or dots that are printed at the same level as the alignment lines and superimposed upon the lines but have a lesser dimension than the lines. An array of such pits or dots or features is printed on the line pattern using a phase shift mask that produces the array of pits or dots. The phase shift mask is a semi-transmissive mask where side lobes are subdued, suppressed or otherwise not considered in reflection, eliminating higher diffraction orders from the reflected image. This means that only the first order is strongly reflected or productive of scattered light directed back for comparison with lines on a higher level mask. The ideal amount of phase shift is 180 degrees in transmission through the phase shift mask.

In the present invention, the dot array of deformations is made on a standard target, such as the SPM AH53 target and printed using diffractive projection at the same level as the line pattern, but with a dimension much less than the line width. Using such a new target, off-axis alignment may be carried out using only a single red laser rather than a red and green laser. Alignment tolerances are significantly reduced with good reproducibility.

### BRIEF DESCRIPTION OF THE DRAWINGS

FIG. 1 is a perspective plan view of a prior art step and scan semiconductor wafer lithography system.

FIG. 2 is a magnified view of an arbitrary alignment target for a step and scan system of the type Shown in FIG. 1.

FIG. 3 is a magnified view of an SPM AH53 alignment target for a step and scan system of the type shown in FIG. 1.

FIGS. 4a and 4b are views of a reticle for making an alignment target in accordance with the present invention.

FIGS. 4c and 4d are views of alignment targets of the present invention for use as improved targets relative to the type shown in FIG. 3.

FIGS. 5a-5d show a manufacturing method for the targets shown in FIGS. 4c-4d.

### DESCRIPTION OF THE PREFERRED EMBODIMENT

With reference to FIG. 2, a portion 21 of an imaged optical target of the prior art, such as would be formed on a wafer using a mask or reticle, is shown. The target consists of spaces 23 at the wafer level 25 separating parallel ridges 27. The thickness of the ridges is a uniform dimension, W, while the spacing between ridges is the uniform dimension, S. The ridges and spaces are formed by means of a mask which exposes photoresist material to actinic radiation. The photoresist is hardened and then etched to form the ridges and spaces. The ridges and spaces diffract light such that lines in the resultant diffraction pattern, including higher order lobes, may be readily viewed by top down observation. Mask layers covering the marks could either obscure the marks, indicating a lack of registration, or allow viewing of the marks, within specified tolerances, indicating registration of the upper layer with the lower layer. Mask layers are stacked with underlying marks indicating registration of an overlying mask. The lowest level target marks may be either on the wafer itself, or on a subsequent mask layer.

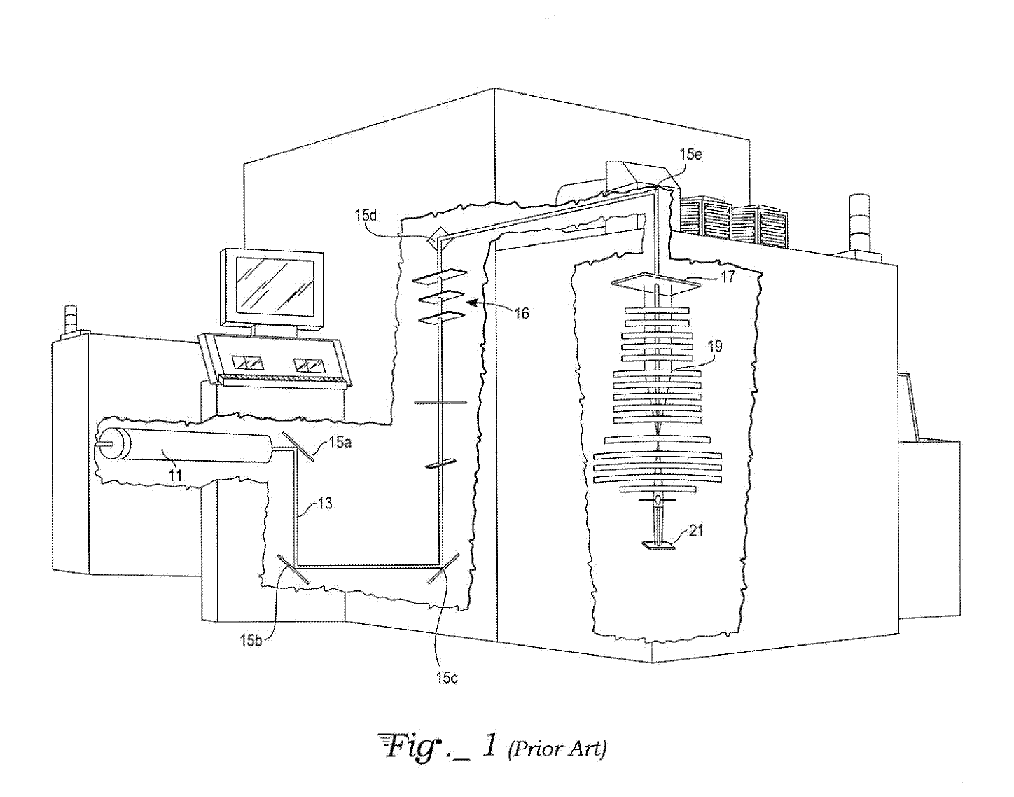

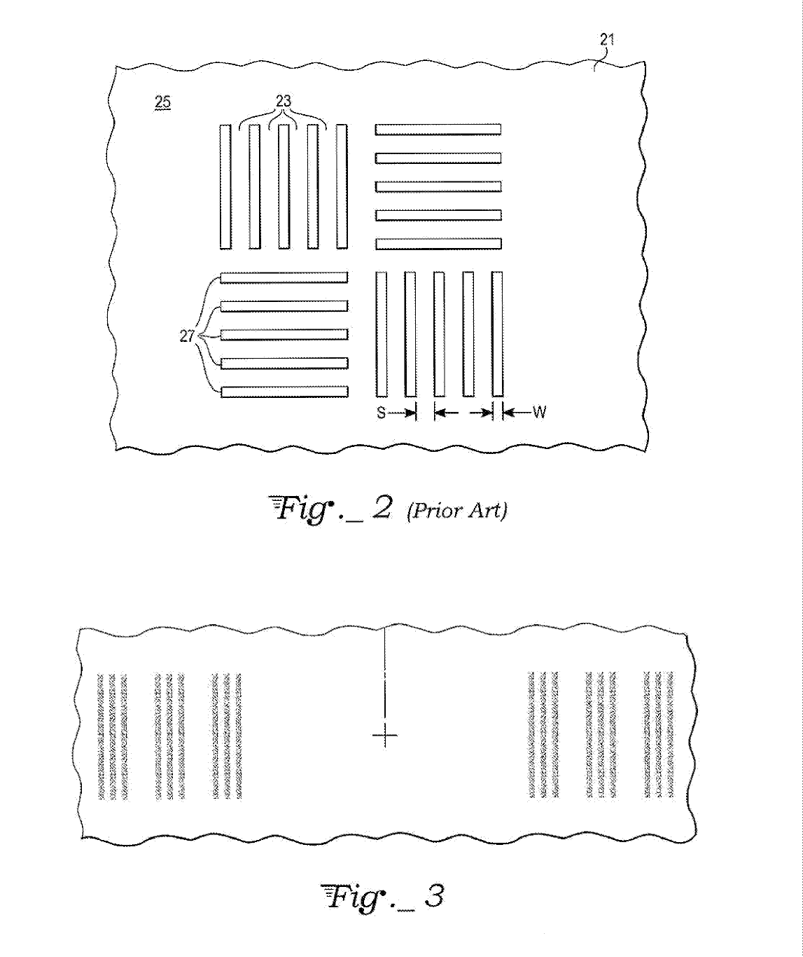

FIG. 3 shows a portion of a particular target specimen known as SPM AH53 that has been modified in accordance with the present invention. This particular target is frequently used for alignment purposes within ASML step and scan system which is the exemplary system illustrated in FIG. 1. In accordance with the present invention, each target stripe is provided with dots as described below.

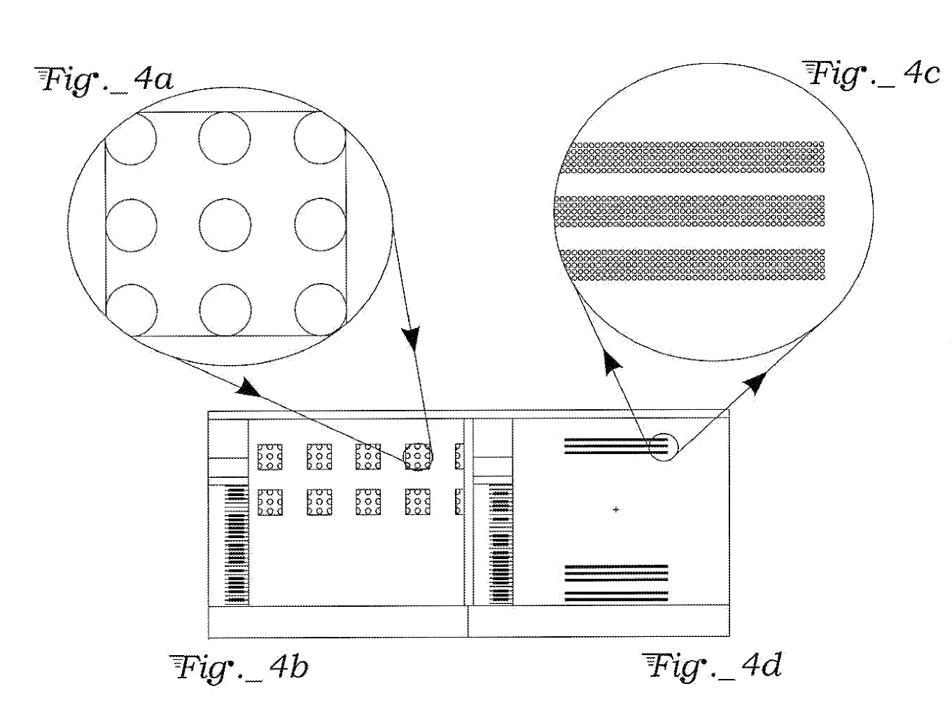

The magnified mask of FIG. 4a is a phase shift mask, seen more fully in FIG. 4b, through which light passes in order to make the targets shown in FIGS. 4c and 4d. FIG. 4c is a magnification of marks shown in the target of FIG. 4d. In each case, the circular marks which appear to be deformation or pits have a normal size of 0.2 microns. FIG. 4d resembles a standard SPM AH53 pattern except that an array of deformations is present at the contact level of each line.

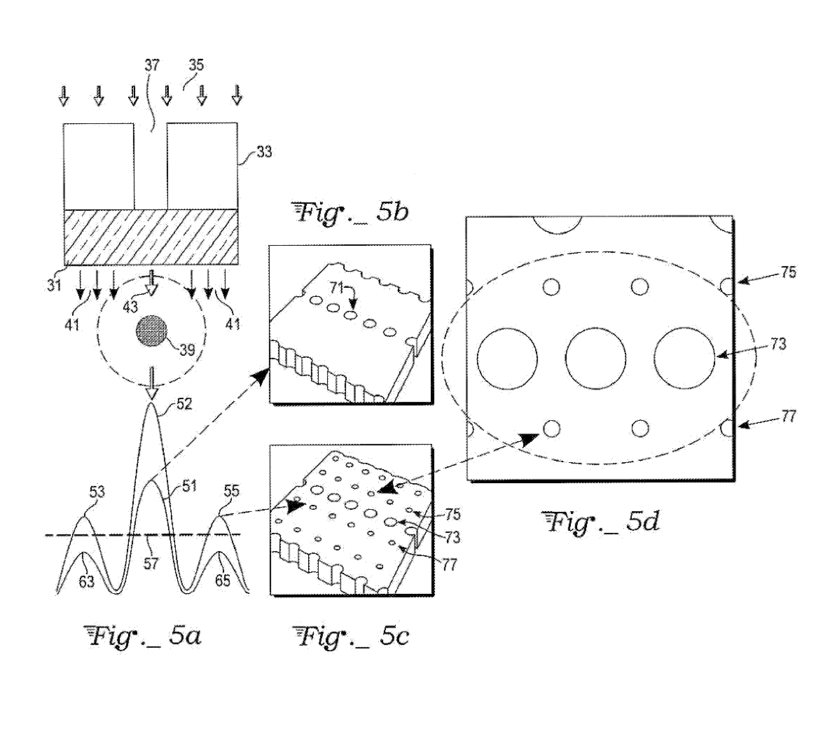

FIGS. 5a-5d illustrate an exemplary manufacturing method in which a reticle quartz substrate 31 carries a partially transmissive mask layer 33 through which a beam of actinic radiation 35 is transmitted. Actinic radiation is that which exposes underlying photoresist and is also used in reading diffractive features of the target, but the reading beam could be a different wavelength. The mask has an aperture 37 through which a principal beam spot 39 is projected in a diffracted light pattern 41 to impinge on photoresist at the wafer level, below dashed line 57. The mask 33 may be, for example, molybdenum-silicon which is nominally six percent transmissive to the actinic radiation producing a phase shift of 180 degrees, plus or minus 3degrees, in the partially transmissive beam 41. Transmissivity of the mask to actinic radiation can be in the range of 6% plus or minus 0.3%. The phase shift of 180 degrees produces an interference pattern relative to the principal beam 43, giving rise to a principal reflected spot 52 plus two second order side lobes 53 and 55.

The side lobes 53 and 55 may be substantially reduced by selecting a resist threshold 57 that will discriminate against the side lobes such that they are at levels 63 and 65, yet the principal reflected spot 51 is above threshold 57. Thus, the principal spot 51 may be seen in reflection or by light scattering but the side lobes 63 and 65 are not seen. Such a resist threshold may be established by the thickness of the photoresist or by other resist properties, such as optical density. The objective is to allow reflection or scattering by the principal lobe 51, but substantially reduce the side lobes 53 and 55 to levels 63 and 65 where they are not seen. If it is seen that side lobes accidentally print, perhaps due to accidental superposition of lobes from different beam spots, the beam spots are adjusted to avoid such superposition of side lobes. Reflection of the principal lobe is illustrated in FIG. 5b where a linear pattern of evenly spaced dots 71 may be seen. On the other hand, FIG. 5c illustrates transmission of side lobes 53 and 55, together with the principal lobe 52, seen as principal row 73 and rows 75 and 77 with smaller dots or features. This results in a greater density of deformations or pits, making the target more difficult to read. A magnification of the second order features in FIG. 5c is shown in FIG. 5d. The second order deformations in rows 75 and 77 are seen to be a fraction of the size of the principal spots in row 73 and do not give as strong a signal in reflection or scattering as the principal dots but nevertheless create a discrimination problem because of the multiplicity of small spots of the side lobes. The desired beam spot pattern is seen in FIG. 5b , with spots spaced more closely together than possible with lithographic formation of line patterns.

In manufacturing semiconductors, a series of masks is aligned with one mask layer above another for deposition of different layers of semiconductor material. Each mask is aligned with an underlying layer having deposited alignment line patterns such as the modified SPM AH53 pattern of the present invention. Deformations in the form of at least one row of evenly spaced pits or features are produced on the line patterns, with suppression of second and higher orders, yielding simple, reproducible mask alignments using a single red laser beam. Although the deformations have been described as preferably being superimposed on alignment lines, the deformations could be used alone or between alignment lines, or both alone and in combination with alignment lines, either superimposed or between the alignment lines. In any event, the deformations should be closely spaced with higher order lobes suppressed.

1. A target for alignment of semiconductor masks comprising:
a plurality of pits diffracting light of a specified wavelength, the pits aligned in rows visible in the surface of a coating over a semiconductor wafer, each pit normally having side lobes, the side lobes suppressed from forming further pits in the coating surface.

2. The target of claim 1 wherein said coating is a plurality of alignment lines in an SPM AH53 target and said pits are on said lines.

3. The target of claim 1 wherein said target is compatible with an ASML stepper.

4. The target of claim 1 having a counterpart reticle with an array of apertures through which said pits are exposed.

5. The target of claim 4 wherein said reticle comprises a semi-transmissive mask.

6. The target of claim 5 wherein said semi-transmissive mask induces a phase shift to actinic radiation through the mask with reference to actinic radiation through said apertures.

7. The target of claim 6 wherein said phase shift is 180°.

8. The target of claim 6 wherein said mask is molybdenum-silicon.

9. The target of claim 6 wherein said mask has transmissivity in the range of 3% to 9%.

10. The target of claim 1, wherein said diffraction pits are readable in red reflected laser light.

11. A target and mask arrangement for alignment of semiconductor masks in a step and scan system comprising:
a phase shift mask having a plurality of apertures therein,
a beam of light of selected wavelength transmitted through the mask, including the apertures, the transmitted beam having an interference pattern, with a principal beam spot and higher order spots,
a substrate coated with light sensitive photoresist receptive of the transmitted beam, the spacing of the apertures productive of light diffractive pits in the photoresist representing principal beam spots, the photoresist having a reflection threshold suppressing the higher order spots.

12. The apparatus of claim 11 wherein the substrate comprises a wafer with a mask alignment line pattern, the light diffractive pits placed in a regular pattern relative to the mask alignment pattern.

13. The apparatus of claim 12 wherein the alignment line pattern is an SPM AH53 target pattern with said light diffractive pits superimposed on lines of the line pattern.

14. The apparatus of claim 11 wherein said phase shift mask has light transmissivity of actinic radiation to the photoresist in the range of 6%, plus or minus 0.3%.

15. The apparatus of claim 15 wherein the phase shift mask is molybdenum silicon on a quartz substrate.

16. A method of aligning semiconductor masks in semiconductor manufacturing on a wafer scale comprising:
patterning a lower level of a wafer with alignment lines of specified width and separation,
patterning the alignment lines using a mask with at least one row of evenly spaced features diffractive of light of a specified wavelength, the features superimposed on the alignment lines,
patterning an upper level of a wafer with alignment lines of a specified width and separation using another mask,
aligning an upper level with a lower level by overlaying alignment marks of the lower and upper level using said features,
repeating patterning and alignment steps until all levels of a wafer have been built.

17. The method of claim 16 further defined by using a partially transmissive mask for patterning the alignment lines with evenly spaced features.

18. The method of claim 17 further defined by suppressing second order and higher features in patterning the alignment lines with at least one row of evenly spaced features.

19. The method of claim 18 further defined wherein the suppressing of second order and higher features is by using a partially transmissive phase shift mask.

20. The method of claim 19 wherein said phase shift mask is a molybdenum-silicon mask having transmissivity in the range of 6%, plus or minus 0.3%.

21. The method of claim 16 wherein the aligning step is by means of directing a beam of laser light of a single color from the top down causing said overlaying of alignment marks.
